(19) United States
(12) Patent Application Publication
(10) Pub. No.: US 2006/0174933 A1
(43) Pub. Date: Aug. 10, 2006

(54) TiO2 aerogel-based photovoltaic electrodes and solar cells

(76) Inventors: Debra Rolison, Arlington, VA (US); Jeremy Pietron, Washington, DC (US); Arnold Stux, Washington, DC (US)

Correspondence Address: NAVAL RESEARCH LABORATORY;ASSOCIATE COUNSEL (PATENTS), CODE 1008.2, 4555 OVERLOOK AVENUE, S.W., WASHINGTON, DC, 20375-5320, US

(21) Appl. No.: 11/052,887

(22) Filed: Feb. 9, 2005

(51) Int. Cl. H01L 31/00

(52) U.S. Cl. 136/256; 136/263

(57) ABSTRACT

A photoelectrode is disclosed having a conductive lead and a titania aerogel in electrical contact with the lead. The aerogel is coated with a photosensitive dye. The photoelectrode may be made by forming a film of a titania aerogel paste on a conductive substrate and coating the film with a dye.

### BACKGROUND OF THE INVENTION

1. Field of the Invention

The invention relates generally to photovoltaic electrodes.

2. Description of the Prior Art

Grätzel and coworkers introduced the porous, nanocrystalline dye-sensitized photovoltaic electrode (dye-sensitized solar cell, DSSC) in 1991. (Regan et al., “A Low-Cost, High Efficiency Solar-Cell Based on Dye-Sensitized Colloidal TiO₂ Films”, Nature, 353, 737-740. All referenced publications and patents are incorporated herein by reference.) Derived from surfactant-templated colloid chemistry, the nanocrystalline interface improved the performance of dye-sensitized semiconductor photoelectrodes by amplifying available surface area to which sensitizing dyes can adsorb, yielding effective surface areas about 500-fold higher than the geometric areas of the film. The high effective concentration of dyes within the film, along with the further development of very efficient, broad-spectrum sensitizing dyes, results in efficient absorption of photons through much of the visible spectrum. Fast electron injection and thermalization kinetics result in efficient injection of dye electrons into the conduction band of the semiconductor film and little competition from direct recombination with the oxidized dye. Charge-transfer mediators easily permeate mesoporous nanocrystalline semiconductor films (typically anatase TiO₂), recharging adsorbed oxidized dyes. The best performance to date with Grätzel cells has yielded global efficiencies of over 10% at 1 sun intensity at AM 1.5 conditions.

One of the remarkable aspects of the Grätzel cell is that the incident photon-to-current conversion efficiency (IPCE) spectrum is much broader than the solution spectra of the dyes. In particular, absorbance in the red portion of the spectrum is higher than would be inferred from solution-phase extinction coefficients of the dyes. The enhanced efficiency in the red is due to the amplified surface area of the nanocrystalline film. Sufficient absorbers are immobilized to give incident photons multiple occasions to be absorbed by TiO₂-bound dye molecules, either by simple element (absorber) redundancy, or by scatter of photons within the film.

Analysis of best performance of the ruthenium-polypyridyl-based dyes, N3 and “the black dye” suggests that global efficiencies could be improved over the current benchmark of 10.4% (which has been unchanged for about 10 years) if IPCE could be increased to near unity between 700 and 900 nm.

Further increasing the specific surface area has been precluded by the current art. For one, the film architecture is fixed and presumed to be optimized. The colloid chemistry, surfactant type, and fractions of solid-to-surfactants have been rigorously explored. Increasing roughness is not an option unless a different film architecture is introduced.

Increasing film thickness has also been presumably eliminated, as most reports describe films no thicker than 12 μm being consistently achievable by the current art. This limit is likely due to two reasons. The more practical reason is that the colloidal pastes do not yield high-quality films at a thickness much greater than 10 μm, because thicker films tend to crack. The second reason is that random-walk statistics of percolative diffusion models for photoelectrons in nanocrystalline semiconductor films predict loss of electron collection efficiency in the presence of excess diffusion space. An outer boundary excessively distal from the current collector may diminish efficiency due to an increased probability of interfacial recombination events as the electron wanders through the semiconductor. The utility of thicker films will depend critically on controlling the surface character of the nanocrystalline film so as to maximize diffusion lengths of electrons within the films and increase the probability of electrons reaching the current-collecting back contact.

### SUMMARY OF THE INVENTION

The invention comprises a photoelectrode comprising a conductive lead and a titania aerogel in electrical contact with the lead. The aerogel is coated with a photosensitive dye.

The invention further comprises a process of making a photoelectrode comprising the steps of: providing a conductive substrate, providing a titania aerogel paste, forming a film of the paste on the substrate, and coating the film with a dye.

### BRIEF DESCRIPTION OF THE DRAWINGS

A more complete appreciation of the invention will be readily obtained by reference to the following Description of the Example Embodiments and the accompanying drawings.

FIG. 1 shows pore distribution, by DFT analysis of nitrogen physisorption isotherms, of TiO₂ aerogel calcined at 425° C. and 500° C.

FIG. 2 schematically shows casting of TiO₂ aerogel film from a composite paste.

FIG. 3 shows X-ray diffraction of TiO₂ aerogel films calcined at (a) 425° C., (b) 500° C., and (c) 30 minutes each at 400, 425, and 480° C. after casting a first layer, second layer, and coating with TiCl₄, respectively.

FIG. 4 shows a scanning electron micrograph (SEM) of a TiO₂ aerogel film.

FIG. 5 schematically shows a cell used to measure photoaction spectra of dye-sensitized TiO₂ aerogel films.

FIG. 6 shows photoaction spectra of thick TiO₂ aerogel films sensitized with Ru(deeb)(bpy)₂(PF₆)₂in 0.5 M LiI/0.050 I₂/CH₃CN, where deeb=4,4′-(n-diethylester) -2,2′-bipyridine and bpy=2,2′-bipyridine

FIG. 7 shows A) photoaction spectra of films ˜2 μm( . . . ), 10-20 μm (−), and 30-35 μm ( - -- )-thick sensitized with Ru(deeb)(bpy)₂(PF₆)₂ taken in 0.5 M LiI/0.050 I₂/CH₃CN and B) those same spectra normalized to the same maximum value to compare spectral width.

FIG. 8 shows a photoaction spectrum of a rough, 12-μm-thick titania aerogel film sensitized with N719 taken in 0.5 M LiI/0.050 I₂/CH₃CN(−) and the spectrum from FIG. 5 ( - - - ) for comparison.

FIG. 9 shows a photoaction spectrum of a two-layer film sensitized with N719.

FIG. 10 shows photoaction spectra at three different illumination intensities: (●) ˜0.5 to 1.6 mW/cm²; (◯) ˜1.3 to 4.0 mW/cm²; (▾)˜9 to 33 mW/cm²; at (A) a two-layer film and (B) a single-layer film.

FIG. 11 compares the ratio of IPCE values measured in the 9 to 33 mW/cm² range to those measured in the 0.5 to 1.6 mW/cm range for (●) a two-layer TiO₂ aerogel film and (◯) a single-layer film at three different wavelengths.

### DETAILED DESCRIPTION OF THE EXAMPLE EMBODIMENTS

In the following description, for purposes of explanation and not limitation, specific details are set forth in order to provide a thorough understanding of the present invention. However, it will be apparent to one skilled in the art that the present invention may be practiced in other embodiments that depart from these specific details. In other instances, detailed descriptions of well-known methods and devices are omitted so as to not obscure the description of the present invention with unnecessary detail.

A strategy is disclosed to fabricate high surface area, ultraporous, nanocrystalline semiconductor films for use in solar cells, with the goal of significantly bettering the performance of the state-of-the-art photoelectrochemical cells using dye-sensitized nanocrystalline semiconductor electrodes. Specifically, TiO₂ aerogels are used as the photoanode material in a dye-sensitized photovoltaic electrode. The semiconductor is expressed as an aerogel due to the very high specific, active surface area and the bicontinuous pore-solid network that the aerogel architecture offers. The high surface area of aerogels allows immobilization of large amounts of sensitizing dyes within the porous volume, thus enabling superior light utilization in dye-sensitized photovoltaics, and offers a large reactive surface area for use in the absence of dyes. The continuous mesoporous network permits high diffusion rates of liquid-phase reactants to the photoelectrode surface, in both sensitized and unsensitized photoelectrodes.

Aerogels are high-surface area, highly porous (˜80-99% porosity) nanostructured materials derived from sol-gel synthesis and supercritical fluid processing methods. (Hüising et al., “Aerogels—Airy Materials: Chemistry, Structure and Properties”, Angew. Chem. Int. Ed., 37, 23-45 (1998).) Aerogels can be made from any material that can be processed as a gel. Outstanding properties include superior surface areas (100-1000 m²/g and more specifically 150-200 m²/g for calcined TiO₂) and a bicontinuous pore-solid network. Primary particles are sized between 10 to 20 nm. The pore network is primarily mesoporous, having a majority pore distribution between 5 to 50 nm. Aerogels are distinguished from the more commonly known xerogels by their relatively greater porosity, but more importantly by the continuity of the pore network throughout the solid, which facilitates diffusive mass transport at near open-medium diffusion rates. Aerogel porosity results from replacement of the pore-filling fluid with liquid carbon dioxide, for example, and subsequent supercritical extraction of the carbon dioxide. These are zero surface tension processes. Supercritical fluid extraction, or supercritical drying, of the wet gels prevents collapse of the pore structure of the wet gel that occurs when drying sol-gel-derived materials by direct evaporation of solvent (which yields xerogels).

The high surface area and fast diffusive mass-transport rates have spurred investigations into the application of aerogel materials as catalysts, battery materials, sensor materials, and supports for fuel-cell catalysts. Expression of functional materials as aerogels has yielded improvement in performance over analogous materials made by other means, and in some cases has revealed new mechanistic components in complex interfacial processes. One-, two-, or more-layer titania aerogel-based photoelectrodes may be fabricated. The high surface area and outstanding diffusional mass-transport characteristics and the approximately fixed bicontinuous, nanoscopic network of titania aerogels can be exploited to achieve IPCE values at 700 nm equivalent to or better than state-of-the-art nanocrystalline electrodes.

In one step of the process, a conductive substrate is provided. The substrate can be any substrate known in the art of photoelectrodes and equivalents thereof, including but not limited to, glass having a fluorine- or indium-doped tin oxide coating. The substrate may be transparent to facilitate the transmission of light though the substrate to the photoactive part of the photoelectrode.

In another step of the process, a titania aerogel paste is provided. The paste may comprise a titania aerogel powder, a surfactant, and a solvent. The paste may be prepared in any manner for combining the ingredients into a paste form. Methods of making titania aerogel into a paste as also known in the art, including, but not limited to, grinding the ingredients together. The pores of the aerogel may have an average size in the range of, but not limited to, about 5 nm to about 50 nm. The aerogel powder may have an average particle size in the range of, but not limited to, about 5 nm to about 20 nm. The powder may be calcined at, for example, about 40° C. or about 425° C.

Suitable surfactants include, but are not limited to, octyl phenol ethoxylate. Suitable solvents include, but are not limited to, a mixture of water and acetylacetonate.

In another step of the process, a film of the paste is formed on the substrate. The film may be formed by any process known in the art for forming a film from a paste, and include, but are not limited to, forming a layer of the paste, drying the layer, and calcining the dried layer. Calcining may be done, for example at about 475° C. or about 500° C.

In another step of the process, the film is coated with a dye. The coating may be done by any method known in the art for coating an aerogel film with a dye. One method is to apply an ethanolic solution of the dye to the film. This step may be done while the substrate is at an elevated temperature such as, but not limited to, about 70° C. to about 100° C. Suitable dyes include, but are not limited to, cis-bis(isothiocyanato)bis(2,2′-bipyridyl-4,4′-dicarboxylato)-ruthenium(II)bistetrabutylammonium (N719) and [bis(2,2′-bipyridine)][(4,4′-(n-diethyl ester-2,2′-bipyridine)]ruthenium(PF₆)₂ (Ru(deeb)(bpy)₂²⁺).

The resulting film may have a thickness of, but not limited to, about 2 μm, about 10 μm, about 20 μm, about 30 μm, about 40 μm, and any thickness in between these values. The film may also be made by forming a plurality of layers from the paste. Such layers may have thicknesses of, but not limited to, about 0.2 μm to about 10 μm. The short wavelength advantages of more finely ground aerogel powders can be added to the long wavelength, long path length advantages of sintered films as long as electrical conductivity between aerogel pieces is good. Preliminary data show that this approach is effective at converting light to electricity through a broader range of the visible spectrum than either the fine powder-derived thin films or the coarse powder-derived thick films. Pastes derived from either coarsely or finely ground aerogels can be used for the second, third, or n^{th} layer.

The resulting structure may be useful as a photoelectrode. The photoelectrode may be made by other processes than those described here and comprises a conductive lead and a titania aerogel coated with a photosensitive dye. The lead can be the substrate as previously described and the aerogel may be in the form of a film coated on the substrate, as previously described. The film may comprise a powder of the titania aerogel or a monolithic aerogel. The photoelectrode can also comprise an electrolyte in contact with the aerogel and a cathode in contact with the electrolyte.

Recently published work focusing on improving performance of dye-sensitized photovoltaic performance in the red portion of the spectrum has included adding a layer of 400-nm titania colloids to improve light scattering within the film (Nazeeruddin, M. K. et al. “A Swift Dye Uptake Procedure for Dye Sensitized Solar Cells”, Chem. Commun. (2003) 1456-1457) and similarly, addition of a colloidal layer that acts as a photonic bandgap material, creating a stop band and also improving light scattering within the film (Nishimura, N. et al. “Standing Wave Enhancement of Red Absorbance and Photocurrent in Dye-Sensitized Titanium Dioxide Photoelectrodes Coupled to Photonic Crystals”, J Am. Chem. Soc. 125 (2003) 6306-6310). The processing flexibility lent by the pre-formed TiO₂ aerogels may allow for accessing thicker films without losing electrical connectedness to the current-collecting FTO contact. The solid part of the nanoscopic aerogel pore-solid network is continuous and therefore electrically “self-wired”. Since as-prepared TiO₂ aerogels are millimeter-sized pieces, which can be ground as coarsely or as finely as desired, films tens of micrometers thick can be readily made. Longer path lengths are more critical at longer wavelengths.

Analysis of contemporary colloidal TiO₂ films show specific surface areas of about 105 to 125 m²/g are achieved in the best performing films, comparable to values of 80-100 m²/g for the best performing aerogel films produced thus far. Use of lower calcination temperatures may result in still higher specific surface areas in the aerogel films.

Titania aerogels can offer advantages in processing flexibility in that they have a pre-programmed architecture that is similar to the architecture, both in terms of surface area and percentage porosity, to the nanocrystalline films typically used in Grätzel-type DSSCs. While the microscopic density of these films may be similar to that of colloid-derived nanocrystalline films, the macroscopic density of our course films may be somewhat lower and can result in somewhat less dye immobilized in the first 2-3 μm of film near the current collector. More translucent films derived from more finely ground aerogel powders may cut down scattering somewhat, as well as facilitating more absorption of shorter wavelength light closer to the current collector, yielding better performance at higher intensities.

Titania aerogels may also serve as effective top layers on conventional nanocrystalline films. As the conventional nanocrystalline films are nearly optimized for performance at full solar intensities, an additional layer, which better harvests photons in the red portion of the spectrum, may be advantageous, and perhaps may perform better than the colloidal scattering layers now employed.

Having described the invention, the following examples are given to illustrate specific applications of the invention. These specific examples are not intended to limit the scope of the invention described in this application.

### EXAMPLE 1

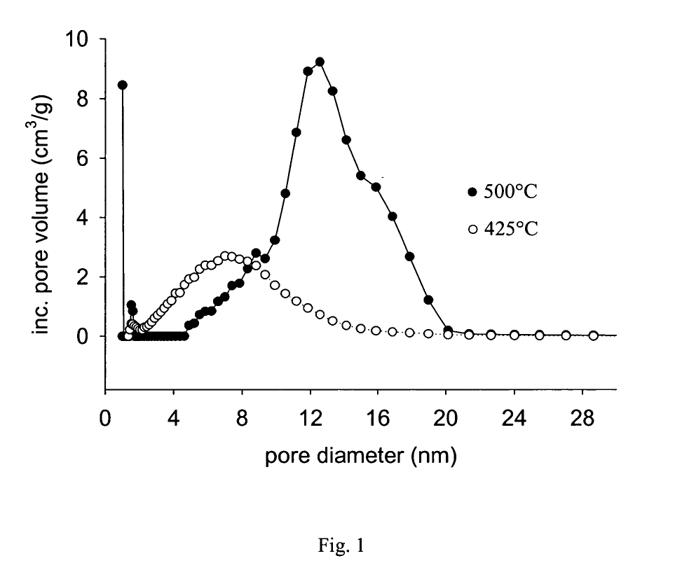

Preparation of TiO₂ aerogel—Titania aerogels were prepared in a manner similar to that described by Dagan et al., “TiO₂ Aerogels for Photocatalytic Decontamination of Aquatic Environments”, J Phys. Chem. 97, 12651-12655 (1993). An ethanolic solution of titanium (IV) isopropoxide was added to a stirred mixture of H₂O, ethanol, and a catalytic amount of nitric acid (typically 63 mg of 70 % nitric acid), yielding a firm, clear gel in minutes. The gel was subsequently aged (typically overnight), rinsed with acetone multiple times over several days, and loaded under acetone into a supercritical dryer (Fisons Bio-Rad E3100) and rinsed with liquid CO₂ before taking the liquid CO₂ above its critical temperature and pressure (T_{c}=31° C., P_{c}=7.4 MPa). The supercritical drier was vented to atmospheric pressure, and the carbon dioxide was released as a gas. The titania aerogels were removed from the dryer and heated in a vacuum oven to remove water at about 100° C. and residual organics at about 200° C., and then calcined in a muffle furnace at 350-425° C., to yield coarse, translucent white pieces, millimeters in size. The titania aerogels were ground to a white powder with an agate mortar and pestle and characterized for surface area and porosity using nitrogen physisorption measurements (at 77K) using a Micrometrics ASAP 2010 accelerated surface area and porosimetry system. Inspection of the nitrogen physisorption isotherm reveals a mesoporous material with pores that are open at both ends. Pore distribution for the aerogel, computed using density functional theory analysis software, is shown in FIG. 1. As is seen here, the majority of the mesopores are in the range of 20 nm.

Porosity and surface area data for representative titania aerogels are summarized in Table 1. Titania aerogels calcined at 425° C. are mesoporous, nanocrystalline anatase materials that are ˜70 % porous with specific surface areas of ˜140 m²/g. The nitrogen physisorption isotherm is characteristic of a mesoporous material with pores that are open at both ends. The pore-size distribution for the titania aerogel is shown in FIG. 1 (●). The majority of the pore volume falls in the 20-nm size range. Surface areas decrease to ˜85 m²/g, the center of the pore distribution shifts to ˜8 nm (◯), and porosity decreases to ˜50% after the aerogels are ground to a powder, cast as a film, and further calcined to 500° C. Porosimetry of titania aerogel ground to powder and calcined multiple times (final calcinations at 470° C.) in the process of making multilayer films also resulted in titania with ˜85 m²/g surface area, pore distributions centered at ˜8 nm, and a porosity of 55% (data not shown).

TABLE 1

| | BET surface | | Average pore diameter |
|---|---|---|---|
| Sample | area (m²/g) | Porosity (%) | (BJH desorption) |
| calcined at 425° C. | 144 | 71 | 14.1 |
| calcined at 425° C., | 85 | 48 | 9.4 |
| ground to powder, | | | |
| calcined at 500° C. | | | |
| calcined at 370° C., | 83 | 55 | 12.4 |
| ground to powder, | | | |
| calcined 2×, final | | | |
| T_{c} = 470° C. | | | |

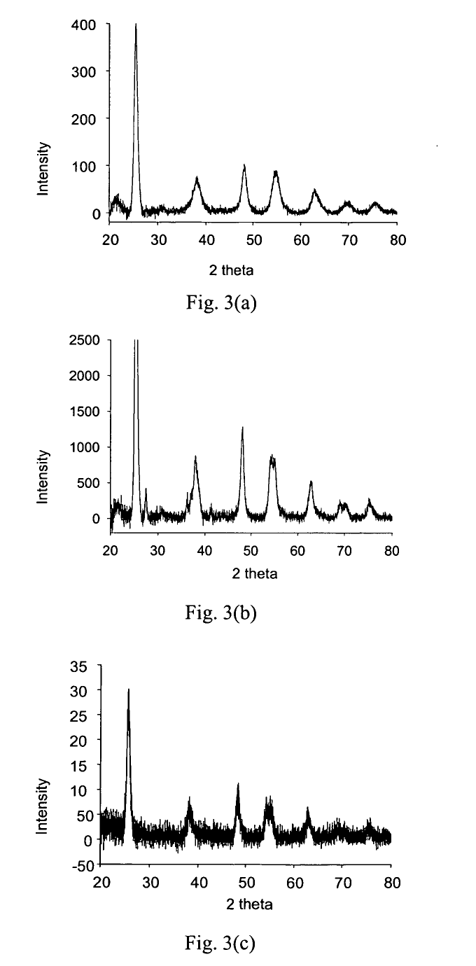

X-ray diffraction of titania aerogels calcined at 425° C. is shown in FIG. 3(a). Comparison to reference diffraction files reveals the presence of anatase TiO₂. Titania aerogels cast as a thick film from pastes and further calcined to 500° C. were still primarily anatase, but showed signs of small amounts of rutile crystal growth, as in FIG. 3(b), as compared to reference diffraction patterns for anatase and rutile TiO₂ FIG. 3(c) represents a powder derived from a paste calcined once at 400° C., again at 425° C. and finally at 480° C., to mimic the conditions when making multilayer films. The diffraction pattern indicates that even after multiple calcinations, no rutile phase develops as long as the final calcination temperature is kept below 500° C.

### EXAMPLE 2

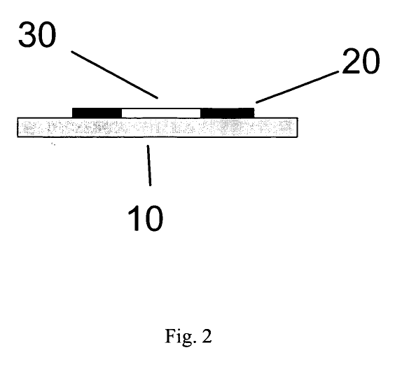

Preparation of aerogel film—Calcined titania aerogel films were constructed by adapting aerogels to the methods of Nazeeruddin et al., “Conversion of Light to Electricity by cis-X₂Bis(2,2′bipyridyl-4,4′-dicarboxylate)ruthenium(II) Charge Transfer Sensitizers (X=C1, Br, I, CN, and SCN) on Nanocrystalline TiO₂ Electrodes”, J Am. Chem. Soc. 115, 6382-6390 (1993). The preparation called for (1) the grinding of 12 g of Degussa P25 with about 4 mL of water and 0.4 mL of acetylacetone (which serves to prevent re-aggregation of particles) in a mortar and pestle, followed by (2) incremental addition of 16 mL of water with continued grinding, followed by the addition of 0.2 mL Triton-X 100. The composite paste was then spread on fluorine-doped tin oxide-coated glass (FTO) and fired at 450-550° C. in air. Titania aerogel preparations were limited to about 1.5 g per batch, primarily by the volume capacity of the supercritical dryer, so the Nazeeruddin procedure was appropriately scaled. The textures of the paste were varied from very viscous to very watery. Viscous to moderately viscous pastes (Method A) resulted from using 0.6 g of TiO₂ aerogel, 0.66 mL of water and about 0.22 mL of 50 mg/mL of Triton-X 100 (Aldrich) in water. Ten to 50 μL of acetylacetone (Aldrich) were added to the paste just as the grinding was begun. More water (˜0.5- 1 mL) was added to thin the paste sufficiently for making films. This paste was spread with a glass pipette onto fluorine-doped tin oxide-coated glass (Pilkington Glass) masked with tape (˜60 -μm thick), FIG. 2, allowed to dry, and then calcined in air for 30 min at 500° C. The Nazeeruddin preparation, when followed exactly as described using Degussa P25, resulted in smooth, 4-12-μm-thick films, which were made for comparison (not shown). When performing this technique with moderately to highly viscous aerogel-derived pastes, topologically rough 10-40-μm-thick films resulted. Alternately, less viscous, further water-thinned, suspensions pipetted onto the masked substrates, allowed to dry, and calcined, yielded smoother, thinner films, typically 2-4-μm thick (Method B). Two-layer films were made by calcining a thin first layer at 400° C., applying a second layer, and calcining the two-layer film at 470-500° C. Some films were post-treated by soaking in freshly made 0.2 M TiCl₄ (aq) (Alfa Aesar) solutions overnight, again as described by Nazeeruddin, which is thought to improve interparticle connectivity within the nanostructured films. Films that were modified with TiC1₄, whether one- or two-layer films, were calcined at somewhat lower temperatures of 400-450° C. before the TiCl₄ coating, and again at 470-500° C. after the coating.

Thick films derived from Method A were topologically rough and nearly opaque. A typical thick film was uneven with features comprising 40-50-μm-thick plateaus and valleys in the 10-μm range. A thinner film made by Method B was more continuous but equally rough. Qualitatively tuning the viscosity of the pastes to intermediate values generated rough but continuous films of intermediate thickness. A two-layer film derived from a thin first layer and a thicker second layer had a rough, continuous topology and a thickness of ˜30 μm.

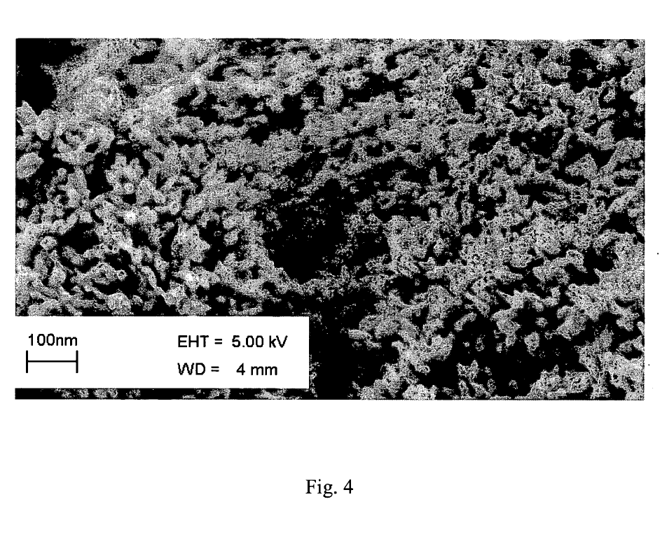

Scanning electron microscopy, shown in FIG. 4, revealed the branched, nanoparticulate structure of the titania aerogel films. Close inspection of the image reveals that the individual micrometer-sized pieces comprising the aerogel film were each nanostructured entities in their own right, which must maintain electrical contact with other micrometer-sized pieces. The images was derived from the top of the second, rougher layer of the film. The thinner first layer, derived from less viscous pastes, was more closely packed on the micrometer scale.

### EXAMPLE 3

Dye coating—Films were coated with dye by soaking in mM ethanolic solutions of cis-bis(isothiocyanato)bis(2,2′-bipyridyl-4,4′-dicarboxylato)-ruthenium(II)bis-tetrabutylammonium (which goes by aliases, including: RuL₂(NCS)₂:2 TBA, or Ruthenium 535 bis-TBA, or N719) from Solaronix (Switzerland), or mM solutions of [bis(2,2′-bipyridine)][(4,4′-(n-diethyl ester-2,2′-bipyridine) ]ruthenium(PF₆)₂, abbreviated Ru(deeb)(bpy)₂²⁺ (a gift from Johns Hopkins University) in CH₃CN, overnight. The films were typically removed from the furnace during cool-down from the calcination while still at ˜80° C. to minimize the level of adsorbed water in the film and then soaked in the sensitizer solutions while still warm.

### EXAMPLE 4

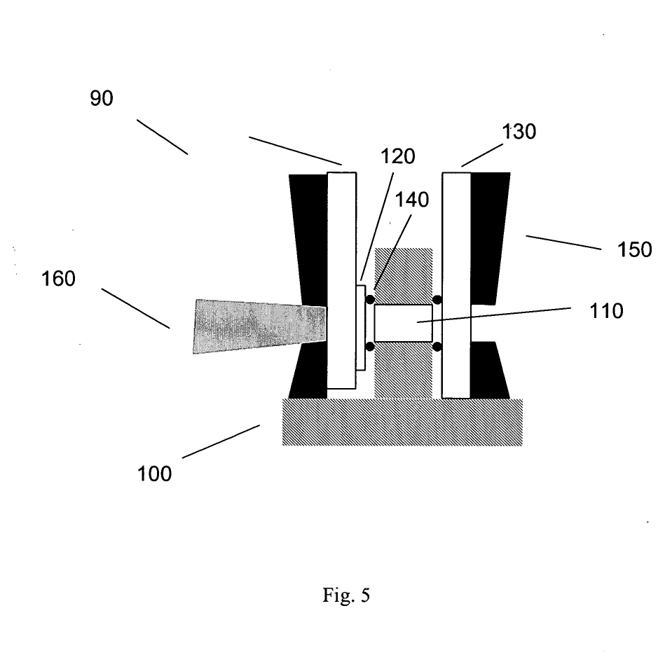

Properties of coated films—Photoaction spectra were taken using a home-built photoelectrochemical cell 90 schematically shown in FIG. 5 that consisted of a Delrin block 100 with a center hole 110 drilled such that the photoanode 120 and the cathode 130 were placed cofacially on opposite sides of the hole. The cell was sealed with o-rings 140, using aluminum plates 150 on the backside of both the photoanode and the cathode, and a nut-and-bolt assembly through the plates to hold the plates and electrodes firmly against the Delrin block. The cathode consisted of a FTO-coated glass electrode that was further coated with Pt deposited from dilute PtC1₆ solution. The center hole in the cell was filled with electrolyte through smaller holes drilled in the top of the block to access the center hole, which along with the front faces of the electrodes and the o-rings, defined the volume of the cell. The electrolyte consisted of acetonitrile (UV Grade, used as-received) or 3-methoxypropionitrile (Aldrich, 98%, used as-received), 0.5 M LiI, and 0.05 M I₂ (both used as-received from Aldrich and stored in a desiccator). In some cases, 4-tert-butylpyridine (Aldrich, 99%, used as-received) was added to the electrolyte to improve the photovoltage of the cell. Illumination 160 was performed with the monochromator and lamp from a SPEX 1681 spectrofluorimeter. Photocurrents were measured using a Hewlett Packard 34401A digital multimeter. The monochromator output was calibrated before and after each series of experiments with an Oriel 835 variable wavelength light/power meter. Films were illuminated from the backside of the TiO₂-coated photoanode during measurements. Current-voltage curves under simulated solar conditions were taken on a Spectrolab X-25 Mark II, featuring a 2.5-kW Xe arc lamp and appropriate filters to simulate AM 0 conditions.

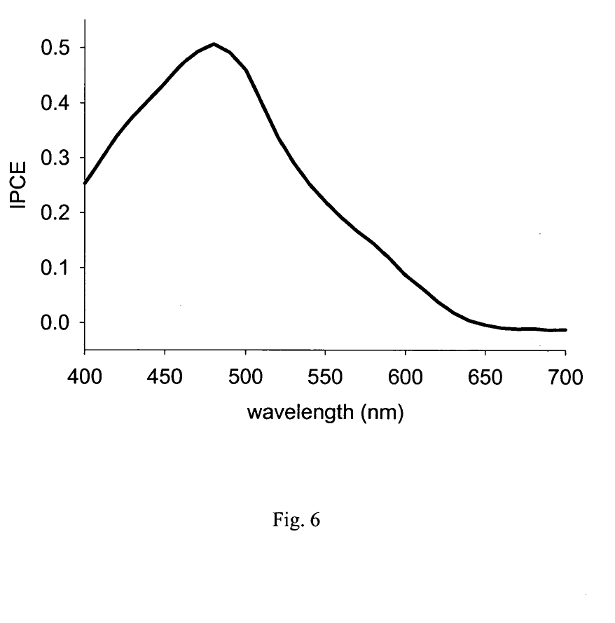

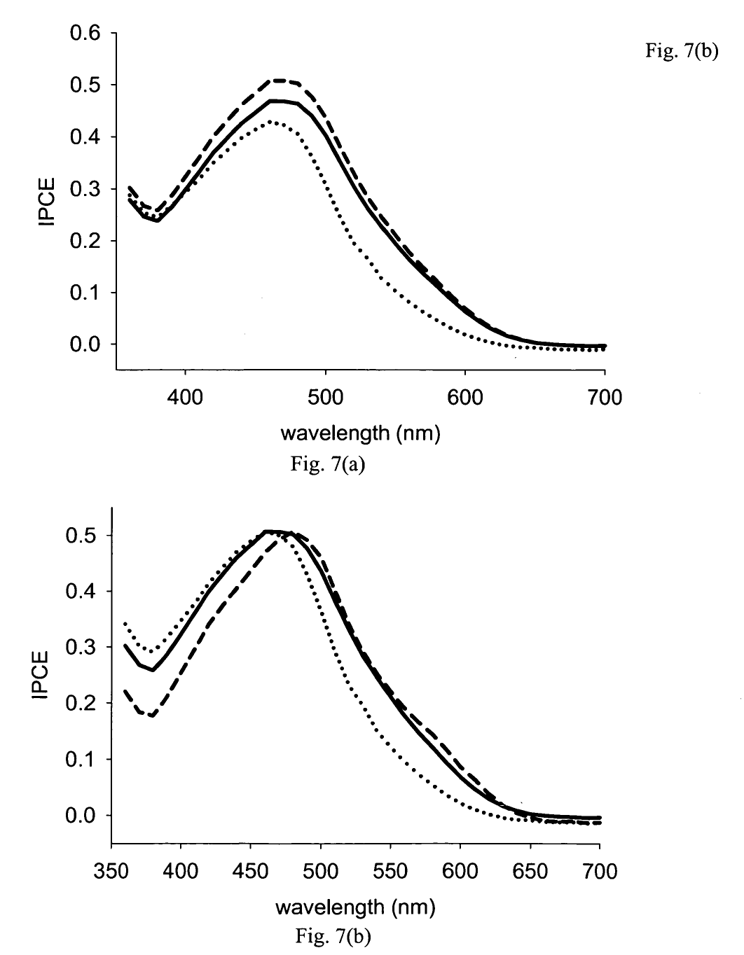

Preliminary IPCE data using Ru(deeb)(bpy)₂(PF₆)₂ as a sensitizer were gathered while determining effects of film processing and thickness on performance. Photoaction spectra of thick TiO₂ aerogel films sensitized with Ru(deeb)(bpy)₂(PF₆)₂ in 0.5 M LiI/0.050 I₂ /CH₃CN are shown in FIG. 6. Maximum incident photon-to-current conversion efficiencies (IPCE) of 50% were measured at 460 nm. Layered structures consisting of translucent films (derived from more dilute pastes) with more opaque overlayers (from thicker pastes) were also made. FIG. 7(a) is a direct comparison of a thin (ca. 2 μm) film ( . . . ), a 2-layer film of intermediate (ca. 10-20 μm) thickness (−), and a thick (ca. 30-35 μm, uneven) film ( - - - ). The IPCE increased monotonically with film thickness. Close inspection of the shape of the curves, however, reveals the importance of both thickness and gross morphology of the films to attained values of IPCE as a function of wavelength. Thicker films make significant gains in the red, while a finely ground film with good substrate coverage is critical below ˜500 nm, regardless of film thickness. FIG. 7(b) features the same three curves re-plotted so that they are all normalized to the same maximum value. The thin film ( . . . ) performs better than the thick film at wavelengths shorter than the IPCE maximum wavelength. Shorter wavelengths are absorbed efficiently by the dye, and are more likely to be efficiently scattered by colloidal TiO₂ centers and absorbed in the first couple micrometers of the film. The films derived from deposition of TiO₂ aerogel powder from dilute pastes are more compactly ordered, as the precipitating particles can slowly form a well-packed film. The thick film ( - - - ) is more effective than the thin film at longer wavelengths, as the more penetrating longer wavelengths that are lost to transmission at thinner films can be absorbed. The two-layer film seems most promising though, as evidenced by its normalized photoaction spectrum (−), which reveals good performance at both ends of the spectrum. Here, the thin layer absorbs the shorter-wavelength photons while the thicker overlayer harvests more of the “red” photons that would have otherwise been lost to transmission. It is unclear whether the thicker layer improves the red photon harvest by virtue of creating more scattering centers, much like the scattering layer described by Nazeeruddin et al., Chem. Commun. 2003(12), 1456-1457 (2003), as described in the introduction, or simply by directly increasing the path length of the film. A more refined study, where the fineness of the aerogel powder is rigorously controlled (e.g., by sieving) so that films of differing thickness can be directly compared, would be required to differentiate scattering effects from path-length effects. In either case, the results in FIG. 7 suggest that a multilayer approach may work best with titania aerogel films as well.

### EXAMPLE 5

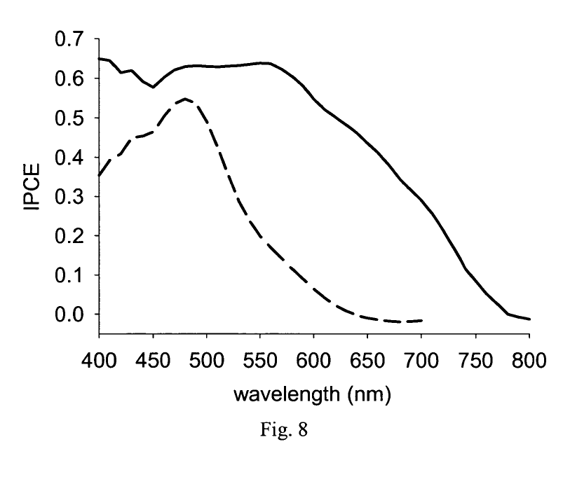

Sensitization with N719—Efficiency depends on both film thickness and excitation intensity. To make more meaningful comparisons to the current state of the art, RuL₂(NCS)₂:2 TBA, or N719 dye was introduced to the films. FIG. 8 (−) is a photoaction spectrum of a rough, 12-μm-thick titania aerogel film sensitized with N719. For comparison, the data from the Ru(deeb)(bpy)₂(PF₆)₂-sensitized film in FIG. 6 are shown ( - - - ). The N719-sensitized electrode has a maximum IPCE value of over 60% extending from about 460 nm to 570 nm before slowly rolling off in the red. This performance is directly comparable to the best results for an untreated film reported by Grätzel and coworkers. Grätzel reports significant improvement in performance of dye-sensitized films upon treatment of the films with 0.1 M aqueous solutions of TiCl₄, where the maximum IPCE values increase from around 60% to over 80%. The reasons for this improvement are somewhat unclear, but reports indicate a slight decrease in porosity after treatment, which has been tentatively interpreted as filling in of the necks between nanoparticles with oligomeric TiO₂, improving particle-to-particle electrical contact.

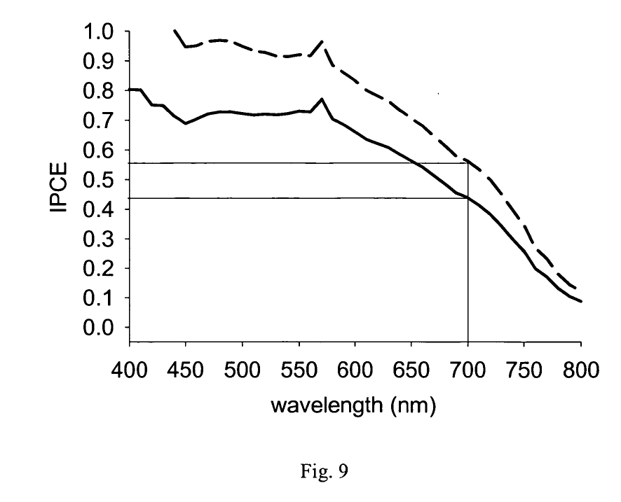

The methods were further modified to attempt to fully exploit the advantage of being able to pre-program the aerogel architecture (particularly porosity and surface chemistry) before casting as a film. Films were cast from pastes derived from aerogels that were calcined initially at lower temperatures ˜350° C., to decrease the crystalline content of the films before subsequent calcinations. The reasoning was that titania (and oxides generally) treated at lower temperatures are richer in surface -OH groups and surface water, which leave the surface active towards further condensation. Upon subsequent calcinations, such surfaces can readily condense with those of other micrometer-sized aerogel pieces within the film. Calcination of the first cast layer was then performed at 400° C., again to keep the layer “active” towards thermally driven condensation chemistry with the second layer. After addition of the second layer, with a post-treatment with TiCl₄ still remaining, it was calcined at 425° C. After soaking in ˜1 M aq. TiCl₄, the multilayer film was calcined at 470° C. and sensitized with N719. Photoaction spectra in FIG. 9 reveal maximum uncorrected IPCE values of 73% (−). Another important feature to note, highlighted by the drop-lines drawn on the figure, is that the uncorrected IPCE value at 700 nm of 43%, is equivalent to the value measured at 700 nm by Nazeeruddin in a nanocrystalline film modified with a scattering layer. The same data corrected for absorbance by the FTO substrates yield the curve represented by the dashed line in FIG. 9. The maximum IPCE is over 90 %, and the IPCE value at 700 nm is ˜56%, which exceeds the state-of-art measurement at 700 nm using N719 in nanocrystalline films. While this correction is not usually performed in the DSSC community, it is relevant here: the FTO-coated glass obtained from Pilkington glass was particularly thick and absorptive; it transmitted <80% of the light over most of the visible spectrum. Given that the best reported IPCE values are 85-90% for N719-type dyes on nanocrystalline films, the photoaction spectra taken to achieve such values must be taken with aerogel-based films supported on more transparent substrates.

### EXAMPLE 6

Experiments at higher light fluence—Preliminary experiments performed on a solar simulator yielded photocurrents of ˜1.5 mA/cm² at 0.5 cm² electrodes, compared to over 20 mA/cm² for the state-of-the-art nanocrystalline electrodes. Very good open-circuit photovoltages of 0.75 V were measured under the same conditions, which is approximately equivalent to those in the best nanocrystalline films. Integration of current-voltage curves gave global efficiency of roughly 0.2%. Given the IPCE values measured at the same electrodes, the photocurrents generated under simulated sunlight were somewhat puzzling. Intensity-dependent IPCE studies on sensitized 1- and 2-layer aerogel films were performed. Photoaction spectra at intensities of 0.5-2 mW/cm², with ˜0.25-cm² spot sizes and excitation linewidths of about 15 nm (estimated from the slit widths in the spectrometer) yielded the relatively high IPCE values shown in FIGS. 6-9. Sunlight at AM 0 has total intensity of 133 mW/cm². Since the aerogel films are nearly opaque over much of the visible spectrum, scattering may become a problem at higher intensities, particularly at the blue end of the spectrum. Rothenberger et al., Sol. Energy Mater. Sol. Cells 58, 321-336 (1999) showed that opaque nanocrystalline films, featuring larger colloids and more disperse pore diameters than transparent films, not only scatter light more intensely than do transparent films, but that the scattering is wavelength dependent between 400 and 1000 nm, rising monotically and increasing by a factor of 5 between 700 nm (the less scattering end) and 400 nm (higher scattering).

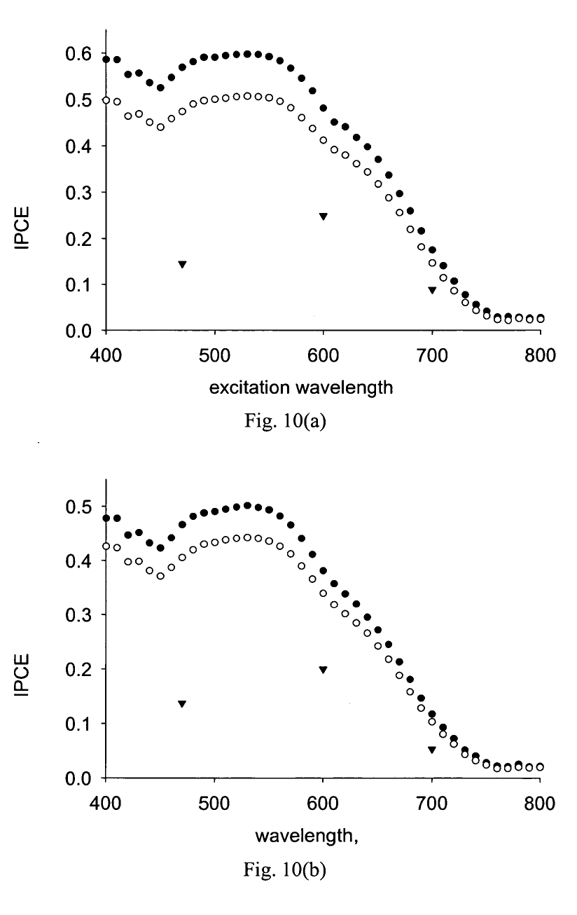

The photoaction spectra in FIG. 10(a) verify that the losses are intensity- and wavelength-dependent. The spectrum obtained at the same intensity as previous spectra (●), (i.e., at 0.5-1.6 mW/cm²) yields a somewhat better efficiency than a spectrum obtained at roughly 2.5 times the intensity (◯), between ˜400-600 nm. At longer wavelengths, the photoaction spectra start to merge as light penetrates the aerogel film much more readily. At still higher intensities (▾) (9-33 mW/cm², depending on wavelength) the loss of efficiency is severe at 470 nm (33 mW/cm²), while significant but less severe at 600 nm (11 mW/cm²) and 700 nm (9 mW/cm²).

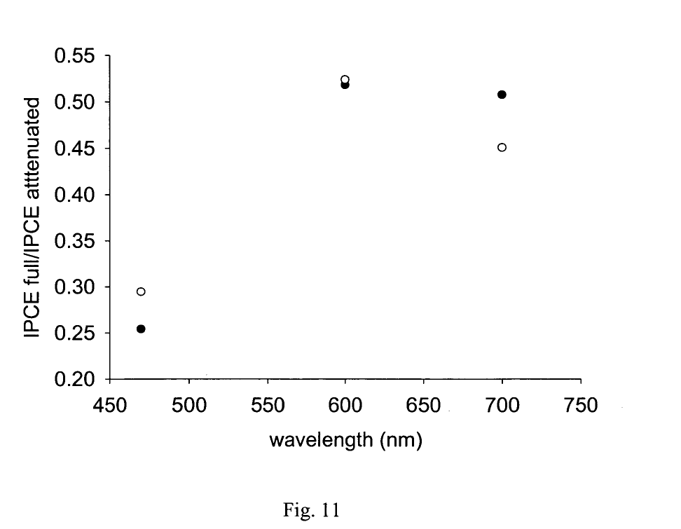

The difference between efficiencies achieved at low light fluence and at higher intensities is likely wavelength-dependent as well as intensity-dependent. FIG. 10(b) shows similar results for a single-layer film. FIG. 11 shows the ratios of efficiency for the photoaction spectra taken in the 9-33 mW/cm² range compared to those in the 0.5-1.6 mW/cm² range. Both electrodes responded similarly (when referenced to their own low-intensity performance) to the intensity change at 470 nm and 600 nm, but at 700 nm, the thicker electrode was the better performer. At all wavelengths and intensities the thicker electrode generally performed better in terms of photocurrent output. The efficiency of the thicker electrode also diminishes less as intensity increases in the red. Rothenberger shows strikingly similar effects of combining transparent and scattering colloids to those multilayer aerogel films derived from combining thicker and thinner film approaches: as with thinner aerogel films, the transparent colloids yield higher output below 600 nm; and similarly to thicker aerogel films, the more scattering colloids yield better photocurrents in the red; when combined, both the colloid preparations and two-layer aerogel films perform well at both ends of the spectrum. Additionally, a more scattering nanocrystalline film absorbs 50% more light at 700 nm than do transparent films. Thus, a significant cause of diminished performance at higher incident intensities may be direct backscattering of much of the light below 600 nm.

Alternately, the coarse nature of the films, while probably making them more scattering in nature, may also allow penetration of light sufficiently deep into the films such that the electrons are injected into films at distances from the current-collecting FTO contact that are greater than the electron diffusion lengths. Peter et al., J. Phys. Chem. B 104, 949-958 (2000) showed through modeling and intensity-modulated photocurrent spectroscopy (IMPS) and intensity-modulated photovoltage spectroscopy (IMVS) that IPCE should be independent of intensity, due to the fact that lifetimes and diffusion lengths of injected electrons are intensity dependent in opposite senses, unless the distance of the electron injection from the current collector exceeds diffusion lengths of the electrons. In such cases an electron concentration profile is generated that peaks within the film, and electrons can diffuse both towards and away from the current collector. The backscattering explanation seems more likely, given that 700-nm light penetrates the film more deeply (thus resulting in possible electron injection at all distances from the current collector) than the shorter wavelengths, yet does not seem to suffer such losses in efficiency at higher intensities.

It is also possible, given the thick cell geometry, that a depletion layer is generated at the counter electrode at higher intensities. Current-time plots at higher light intensities (not shown) reveal a current that decays to a steady-state over seconds to minutes, depending on wavelength and intensity of light.

Barb\acute{e}et al., J. Am. Ceram. Soc. 80, 3157-3171 (1997) report a loss of efficiency at 1 Sun intensity compared to 1/10 Sun intensity when using films with average pore sizes of 4 nm, while realizing no losses when the average pore size is closer to 20 nm. They attribute this loss to mass-transport limitations in the smaller-pore film. Here, the average pore size is ˜8 nm before treatment of the film with TiCl₄, and may shrink somewhat upon treatment of the film with TiCl₄. It is possible that the combination of small pore size and thick films may conspire to create a mass-transport bottleneck in the films at higher intensity.

Obviously, many modifications and variations of the present invention are possible in light of the above teachings. It is therefore to be understood that the claimed invention may be practiced otherwise than as specifically described.

What is claimed is:

1. A photoelectrode comprising:
a conductive lead; and
a titania aerogel in electrical contact with the lead;
wherein the aerogel is coated with a photosensitive dye.

2. The photoelectrode of claim 1, wherein the aerogel comprises pores having an average diameter of from about 5 nm to about 50 nm.

3. The photoelectrode of claim 1, wherein the lead is a substrate and the aerogel is in the form of a film coated on the substrate.

4. The photoelectrode of claim 3, wherein the film comprises a powder of the titania aerogel.

5. The photoelectrode of claim 4, wherein the average particle size of the powder is from about 5 nm to about 20 nm.

6. The photoelectrode of claim 5, wherein the film is about 2 μm to about 10 μm thick.

7. The photoelectrode of claim 4, wherein the film is about 10 μm to about 20 μm thick.

8. The photoelectrode of claim 4, wherein the film is about 20 μm to about 30 μm thick.

9. The photoelectrode of claim 4, wherein the film is about 30 μm to about 40 μm thick.

10. The photoelectrode of claim 4, wherein the film comprises a plurality of layers comprising the powder of the titania aerogel.

11. The photoelectrode of claim 10, wherein each of the plurality of layers is about 0.2 μm to about 10 μm thick

12. The photoelectrode of claim 3, wherein the substrate comprises fluorine-doped tin oxide-coated glass.

13. The photoelectrode of claim 3, wherein the substrate comprises indium-doped tin oxide-coated glass.

14. The photoelectrode of claim 1, wherein the dye is cis-bis(isothiocyanato)bis(2,2′-bipyridyl-4,4′-dicarboxylato)-ruthenium(II)bis-tetrabutylammonium.

15. The photoelectrode of claim 1, wherein the dye is [bis(2,2′-bipyridine)][(4,4′-(n-diethyl ester-2,2′-bipyridine)]ruthenium(PF₆)₂.

16. The photoelectrode of claim 1, further comprising:
an electrolyte in contact with the titania aerogel; and
a cathode in contact with the electrolyte.

17. A process of making a photoelectrode comprising the steps of:
providing a conductive substrate;
providing a titania aerogel paste;
forming a film of the paste on the substrate; and
coating the film with a dye.

18. The process of claim 17, wherein the paste comprises:
a titania aerogel powder;
a surfactant; and
a solvent.

19. The process of claim 18, wherein the surfactant is octyl phenol ethoxylate

20. The process of claim 18, wherein the solvent is a mixture of water and acetylacetonate.

21. The process of claim 17, wherein the film is formed by:
forming a layer of the paste on the substrate;
drying the layer; and
calcining the dried layer.

22. The process of claim 17, wherein the coating is performed by applying an ethanolic solution of the dye to the film.

23. The process of claim 22, wherein the coating is performed when the substrate is at a temperature of from about 70° C. to about 100° C.

24. The process of claim 17, wherein the substrate is transparent.
